(19) United States
(12) Patent Application Publication
(10) Pub. No.: US 2026/0333585 A1
(43) Pub. Date: Oct. 22, 2026

(54) ELECTRONIC DEVICE AND METHOD FOR MANUFACTURING ELECTRONIC DEVICE

(71) Applicant: FUJI ELECTRIC CO., LTD., Kawasaki-shi (JP)

(72) Inventor: Hiroaki HOKAZONO, Tokyo (JP)

(73) Assignee: FUJI ELECTRIC CO., LTD., Kawasaki-shi (JP)

(21) Appl. No.: 19/565,481

(22) Filed: Mar. 12, 2026

(30) Foreign Application Priority Data
Apr. 16, 2025 (JP) 2025-067627

(51) Int. Cl. H05K 1/181; H05K 3/341

(52) U.S. Cl. CPC H05K 1/181; H05K 3/341

(57) ABSTRACT

An electronic device, including: an electronic module including a plurality of electrodes provided on a principal surface thereof; and a printed circuit board. The printed circuit board includes: a mounting surface on which the electronic module is mounted, a mounting region being defined on the mounting surface, and a plurality of conductive patterns provided in the mounting region, the plurality of conductive patterns respectively corresponding to the plurality of electrodes and being respectively bonded to the plurality of electrodes via a bonding member. Each of the plurality of conductive patterns has at least one portion that faces an outer edge of the mounting region and extends toward the outer edge beyond one of the plurality of electrodes corresponding to that conductive pattern.

### CROSS-REFERENCE TO RELATED APPLICATION(S)

This application is based upon and claims the benefit of priority of the prior Japanese Patent Application No. 2025-067627, filed on Apr. 16, 2025, the entire contents of which are incorporated herein by reference.

### BACKGROUND OF THE INVENTION

### 1. Field of the Invention

The embodiment discussed herein relates to an electronic device and a method for manufacturing the electronic device.

### 2. Background of the Related Art

An electronic device includes an element having a protrusion or an electrode on a lower surface, and a substrate having a conductive layer on an upper surface. The electronic device further includes a bonding member that bonds the protrusion or the electrode of the element to the conductive layer of the substrate (for example, see Japanese Laid-open Patent Publication No. 2012-243922, Japanese Laid-open Patent Publication No. 2002-076057, and Japanese Laid-open Patent Publication No. 2014-187394).

### SUMMARY OF THE INVENTION

According to an aspect of the present disclosure, there is provided an electronic device including: an electronic module including a plurality of electrodes provided on a principal surface thereof; and a printed circuit board, including: a mounting surface on which the electronic module is mounted, a mounting region being defined on the mounting surface, and a plurality of conductive patterns provided in the mounting region, the plurality of conductive patterns respectively corresponding to the plurality of electrodes and being respectively bonded to the plurality of electrodes via a bonding member, wherein each of the plurality of conductive patterns has at least one portion that faces an outer edge of the mounting region and extends toward the outer edge beyond one of the plurality of electrodes corresponding to that conductive pattern.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device (excluding a cooling module) according to an embodiment;

FIG. 2 is a cross-sectional view of the semiconductor device according to the embodiment;

FIG. 3 is a perspective view of a semiconductor module according to the embodiment;

FIG. 4 is a plan view of a mounting region of a printed circuit board included in a wiring module according to the embodiment;

FIG. 5 is a first side view of the wiring module to which the semiconductor module according to the embodiment is bonded;

FIG. 6 is a second side view of the wiring module to which the semiconductor module according to the embodiment is bonded;

FIG. 7 illustrates steps of a manufacturing method of the semiconductor device according to the embodiment;

FIG. 8 illustrates a solder application step of the manufacturing method of the semiconductor device according to the embodiment;

FIG. 9 illustrates a semiconductor module placement step of the manufacturing method of the semiconductor device according to the embodiment;

FIG. 10 illustrates a bonding step (heating) of the manufacturing method of the semiconductor device according to the embodiment;

FIG. 11 illustrates the bonding step (heating and depressurizing) of the manufacturing method of the semiconductor device according to the embodiment;

FIG. 12 illustrates a bonding step (heating) of a manufacturing method of a different semiconductor device (part 1);

FIG. 13 illustrates the bonding step (heating) of the manufacturing method of the different semiconductor device (part 2); and

FIG. 14 illustrates the bonding step (heating and depressurizing) of the manufacturing method of the different semiconductor device.

### DETAILED DESCRIPTION OF THE INVENTION

Hereinafter, an embodiment will be described with reference to the drawings. Throughout the following embodiment, the term “upper surface” refers to a surface facing upward when viewed from the plane of the sheet. Similarly, “upper side”, “upper portion”, and “upward direction” refer to directions facing upward when viewed from the plane of the sheet. The term “lower surface” refers to a surface facing downward when viewed from the plane of the sheet. Similarly, “lower side”, “lower portion”, and “downward direction” refer to directions facing downward when viewed from the plane of the sheet. These directional indications have the same meaning in all drawings. The expressions “upper surface”, “upper side”, “upper portion”, “upward direction”, “lower surface”, “lower side”, “lower portion”, and “downward direction” are merely convenient expressions for specifying relative positional relationships and do not limit the technical concept of the present disclosure. Throughout the following embodiment, the term “main component” indicates a case in which an amount of 80 vol % or more is included. Similarly, the term “substantially identical” indicates a case in which a range within ±10% is included. The terms “perpendicular”, “orthogonal”, and “parallel” indicate ranges within ±10°.

### Embodiment

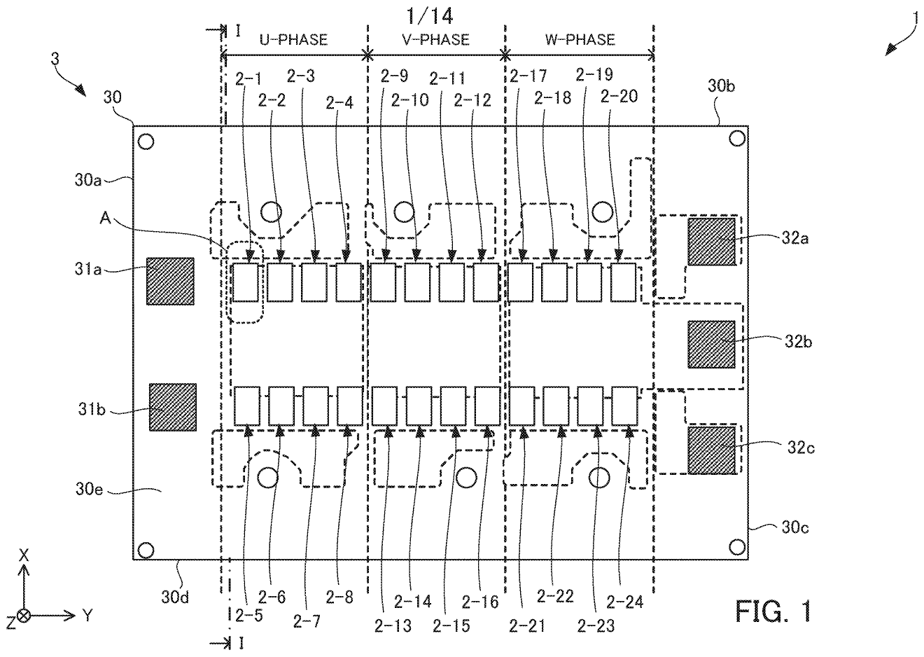

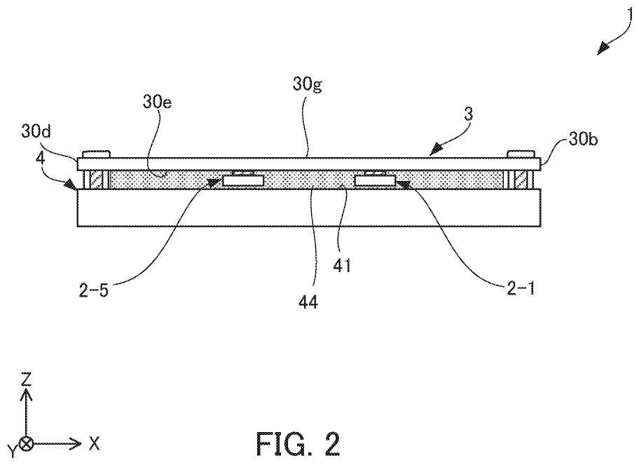

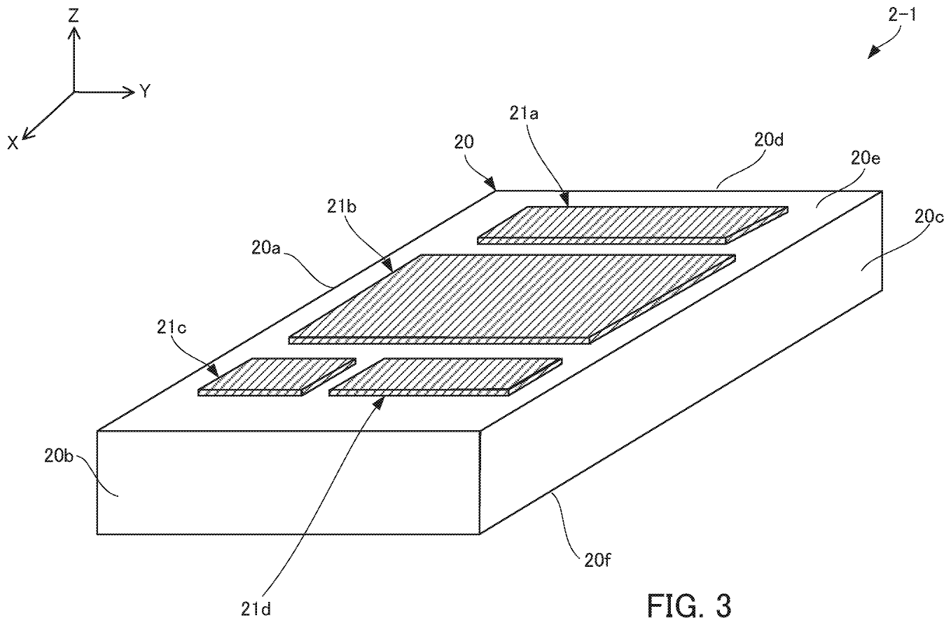

An electronic device according to an embodiment is described below. Here, as an example of the electronic device, a semiconductor device is described with reference to FIGS. 1 to 3. FIG. 1 is a plan view of a semiconductor device (excluding a cooling module) according to an embodiment. FIG. 2 is a cross-sectional view of the semiconductor device according to the embodiment. FIG. 3 is a perspective view of a semiconductor module according to the embodiment. FIG. 1 illustrates, in plan view, a lower-surface side of a semiconductor device 1 of FIG. 2 in which a cooling module 4 is removed. FIG. 2 is a cross-sectional view taken along the dot-dash line I-I in FIG. 1.

The semiconductor device 1 includes a plurality of semiconductor modules, a wiring module 3, and the cooling module 4. A plurality of semiconductor modules 2-1, 2-2, 2-3, 2-4, 2-5, 2-6, 2-7, and 2-8 is mounted on a mounting surface 30e, which is the principal surface of a printed circuit board 30 included in the wiring module 3. A plurality of semiconductor modules 2-9, 2-10, 2-11, 2-12, 2-13, 2-14, 2-15, and 2-16 is mounted on the mounting surface 30e of the printed circuit board 30. A plurality of semiconductor modules 2-17, 2-18, 2-19, 2-20, 2-21, 2-22, 2-23, and 2-24 is mounted on the mounting surface 30e of the printed circuit board 30.

The semiconductor modules 2-1, 2-2, 2-3, and 2-4, the semiconductor modules 2-9, 2-10, 2-11, and 2-12, and the semiconductor modules 2-17, 2-18, 2-19, and 2-20 are arranged in a row along a side surface 30b and a side surface 30d of the printed circuit board 30. These semiconductor modules constitute upper arms of respective phases.

The semiconductor modules 2-5, 2-6, 2-7, and 2-8, the semiconductor modules 2-13, 2-14, 2-15, and 2-16, and the semiconductor modules 2-21, 2-22, 2-23, and 2-24 are arranged in a row along the side surface 30b and the side surface 30d of the printed circuit board 30. These semiconductor modules constitute lower arms of respective phases.

The plurality of semiconductor modules all has the same configuration. When the plurality of semiconductor modules is not distinguished, reference numerals may be omitted. In the following description, the semiconductor module 2-1 among the plurality of semiconductor modules is described as an example.

The semiconductor module 2-1 is an example of an electronic module. The semiconductor module 2-1 includes a molded body 20. The molded body 20 encapsulates a semiconductor chip (not illustrated) therein. The semiconductor chip may be a power metal-oxide-semiconductor field-effect transistor (MOSFET) having silicon carbide as a main component. The semiconductor chip may alternatively be configured with gallium nitride as a main component. The power MOSFET may include a body diode functioning as a free-wheel diode (FWD). In this case, a control electrode (gate electrode) and an output electrode (source electrode), which is a main electrode, are provided on an upper surface of the semiconductor chip. An input electrode (drain electrode), which is a main electrode, is provided on a lower surface of the semiconductor chip.

The semiconductor chip may include a switching device configured with silicon as a main component. The switching device may be, for example, a reverse conducting-insulated gate bipolar transistor (RC-IGBT). The RC-IGBT is a semiconductor device in which an IGBT and an FWD are configured in reverse parallel within a single chip. In this case, a control electrode (gate electrode) and an output electrode (emitter electrode), which is a main electrode, are provided on an upper surface of the semiconductor chip. An input electrode (collector electrode), which is a main electrode, is provided on a lower surface of the semiconductor chip.

The molded body 20 has a rectangular parallelepiped shape. The molded body 20 includes an electrode surface 20e, which is a principal surface, a heat dissipation surface 20f, and side surfaces 20a, 20b, 20c, and 20d. The electrode surface 20e has a rectangular shape in plan view. A first electrode 21a, a second electrode 21b, a third electrode 21c, and a fourth electrode 21d are exposed from the electrode surface 20e. Details of the first electrode 21a, the second electrode 21b, the third electrode 21c, and the fourth electrode 21d are described later. The heat dissipation surface 20f is on an opposite side of the electrode surface 20e and faces the electrode surface 20e. The size and shape of the heat dissipation surface 20f are the same as the size and shape of the electrode surface 20e.

The side surfaces 20a, 20b, 20c, and 20d sequentially surround the electrode surface 20e and the heat dissipation surface 20f on four sides. The side surfaces 20a and 20c extend along a longitudinal direction of the electrode surface 20e and the heat dissipation surface 20f. The side surfaces 20a and 20c also extend along a short-side direction (side surfaces 30a and 30c) of the printed circuit board 30. The side surfaces 20b and 20d extend along a short-side direction of the electrode surface 20e and the heat dissipation surface 20f. The side surfaces 20b and 20d also extend along a longitudinal direction (the side surfaces 30b and 30d) of the printed circuit board 30.

The molded body 20 may be configured with a thermosetting resin. Examples of the thermosetting resin include an epoxy resin, a phenol resin, a maleimide resin, and a polyester resin. The molded body 20 may further include a filler. The filler may include a material having insulation properties and high thermal conductivity as a main component. Examples of the material include silicon oxide, aluminum oxide, boron nitride, and aluminum nitride. A content of the filler may be 10 vol % or more and 70 vol % or less relative to the entirety of the molded body 20.

The first electrode 21a, the second electrode 21b, the third electrode 21c, and the fourth electrode 21d protrude upward from the electrode surface 20e of the molded body 20 and are exposed. A protrusion amount (thickness) of the first electrode 21a, the second electrode 21b, the third electrode 21c, and the fourth electrode 21d from the electrode surface 20e of the molded body 20 may be substantially uniform. The first electrode 21a, the second electrode 21b, the third electrode 21c, and the fourth electrode 21d are electrically connected, inside the molded body 20, to various electrodes included in the semiconductor chip.

The first electrode 21a, the second electrode 21b, the third electrode 21c, and the fourth electrode 21d may each have a rectangular shape. On the other hand, respective sizes of the first electrode 21a, the second electrode 21b, the third electrode 21c, and the fourth electrode 21d differ from one another.

The first electrode 21a extends along a short-side direction of the electrode surface 20e on a side of the side surface 20d of the electrode surface 20e.

The second electrode 21b is provided in a vicinity of a central portion of the electrode surface 20e. The length of the second electrode 21b parallel to the short-side direction of the electrode surface 20e is longer than the length of the first electrode 21a in the same direction.

The third electrode 21c is provided along each of the side surface 20a and the side surface 20b of the electrode surface 20e. The length of the third electrode 21c parallel to a longitudinal direction of the electrode surface 20e is substantially equal to the length of the first electrode 21a in the same direction. The length of the third electrode 21c parallel to the short-side direction of the electrode surface 20e is shorter than the length of the first electrode 21a in the same direction.

The fourth electrode 21d is provided along each of the side surface 20c and the side surface 20b of the electrode surface 20e. The length of the fourth electrode 21d parallel to the longitudinal direction of the electrode surface 20e is substantially equal to the length of the first electrode 21a in the same direction. The length of the fourth electrode 21d parallel to the short-side direction of the electrode surface 20e is longer than the length of the third electrode 21c in the same direction.

The first electrode 21a, the second electrode 21b, the third electrode 21c, and the fourth electrode 21d are arranged asymmetrically with respect to the electrode surface 20e of the molded body 20 and are neither line-symmetric nor point-symmetric. In plan view, the center of gravity of the first electrode 21a, the second electrode 21b, the third electrode 21c, and the fourth electrode 21d (four mass points) does not coincide with the center of gravity of the electrode surface 20e of the molded body 20. This is a case in which the first electrode 21a, the second electrode 21b, the third electrode 21c, and the fourth electrode 21d have the same thickness and are configured with the same material. A cause of the non-coincidence of the centers of gravity is not limited to differences in shapes, differences in sizes, and variations in positions of the first electrode 21a, the second electrode 21b, the third electrode 21c, and the fourth electrode 21d. A cause of the non-coincidence of the centers of gravity includes, for example, wiring routes inside the molded body 20.

The first electrode 21a, the second electrode 21b, the third electrode 21c, and the fourth electrode 21d are configured with a material having excellent conductivity. Examples of the material include copper, aluminum, and an alloy including at least one of these. Plating treatment may be performed on respective surfaces of the first electrode 21a, the second electrode 21b, the third electrode 21c, and the fourth electrode 21d. A plating material having excellent corrosion resistance is used. Examples of the plating material include nickel, a nickel-phosphorus alloy, and a nickel-boron alloy.

The wiring module 3 includes the printed circuit board 30, a positive electrode terminal 31a, a negative electrode terminal 31b, and output terminals 32a, 32b, and 32c. The printed circuit board 30 may have a flat-plate shape. The printed circuit board 30 includes a plurality of laminated conductive circuit layers (not illustrated).

The plurality of conductive circuit layers may include a conductive circuit layer through which a main current flows (main current circuit layer), a conductive circuit layer through which a control current flows (control circuit layer), and a conductive circuit layer through which an auxiliary source current flows (auxiliary source circuit layer). These conductive circuit layers are laminated via an insulating member and are electrically insulated. Each conductive circuit layer has a foil shape and is patterned into a predetermined shape. Each conductive circuit layer is configured with a material having excellent conductivity. Examples of the material include copper, aluminum, and an alloy containing at least one of these as a main component.

An outer periphery of the printed circuit board 30 includes the side surfaces 30a, 30b, 30c, and 30d, the mounting surface 30e, and an upper surface 30g. The mounting surface 30e has a rectangular shape in plan view. The upper surface 30g is on an opposite side of the mounting surface 30e and faces the mounting surface 30e. The size and shape of the upper surface 30g are the same as the size and shape of the mounting surface 30e.

The side surfaces 30a, 30b, 30c, and 30d sequentially surround four sides of the mounting surface 30e and the upper surface 30g. The side surfaces 30a and 30c extend along a short-side direction of the mounting surface 30e and the upper surface 30g. The side surfaces 30b and 30d extend along a longitudinal direction of the mounting surface 30e and the upper surface 30g.

The plurality of semiconductor modules is respectively mounted on the mounting surface 30e. Depending on shapes of patterns of the conductive circuit layers included in the printed circuit board 30, the plurality of semiconductor modules may each be mounted in the same orientation with respect to the mounting surface 30e of the wiring module 3. Alternatively, a plurality of semiconductor modules in one row on a side of the side surface 30b and a plurality of semiconductor modules in one row on a side of the side surface 30d may be mounted on the mounting surface 30e in opposite orientations.

A plurality of mounting regions (described later) is set on the mounting surface 30e. The plurality of semiconductor modules is respectively mounted in the plurality of mounting regions. In the mounting regions, a plurality of conductive patterns on which the first electrode 21a, the second electrode 21b, the third electrode 21c, and the fourth electrode 21d of the semiconductor module are arranged are provided. These conductive patterns are included in respective conductive circuit layers. The plurality of conductive patterns of the mounting regions and the first electrode 21a, the second electrode 21b, the third electrode 21c, and the fourth electrode 21d of the semiconductor module are respectively bonded with solder. Details of this bonding are described later.

Alternating current of a U-phase is output from the output terminal 32a (described later) by the semiconductor modules 2-1, 2-2, 2-3, 2-4, 2-5, 2-6, 2-7, and 2-8 mounted on the mounting surface 30e. Alternating current of a V-phase is output from the output terminal 32b (described later) by the semiconductor modules 2-9, 2-10, 2-11, 2-12, 2-13, 2-14, 2-15, and 2-16 mounted on the mounting surface 30e. Alternating current of a W-phase is output from the output terminal 32c (described later) by the semiconductor modules 2-17, 2-18, 2-19, 2-20, 2-21, 2-22, 2-23, and 2-24 mounted on the mounting surface 30e.

The positive electrode terminal 31a and the negative electrode terminal 31b are formed along a side of the side surface 30a of the mounting surface 30e of the printed circuit board 30. The positive electrode terminal 31a is electrically connected respectively to input electrodes of the plurality of semiconductor chips through a predetermined conductive circuit layer of the printed circuit board 30. The negative electrode terminal 31b is electrically connected respectively to output electrodes of the plurality of semiconductor chips through a predetermined conductive circuit layer of the printed circuit board 30.

The output terminals 32a, 32b, and 32c are formed along a side of the side surface 30c of the mounting surface 30e of the printed circuit board 30. The output terminal 32a corresponds to the U-phase and is electrically connected respectively to output electrodes of the semiconductor modules 2-1, 2-2, 2-3, and 2-4 and to input electrodes of the semiconductor modules 2-5, 2-6, 2-7, and 2-8 through a predetermined conductive circuit layer of the printed circuit board 30.

The output terminal 32b corresponds to the V-phase and is electrically connected respectively to output electrodes of the semiconductor modules 2-9, 2-10, 2-11, and 2-12 and to input electrodes of the semiconductor modules 2-13, 2-14, 2-15, and 2-16 through a predetermined conductive circuit layer of the printed circuit board 30. The output terminal 32c corresponds to the W-phase and is electrically connected respectively to output electrodes of the semiconductor modules 2-17, 2-18, 2-19, and 2-20 and to input electrodes of the semiconductor modules 2-21, 2-22, 2-23, and 2-24 through a predetermined conductive circuit layer of the printed circuit board 30.

The cooling module 4 includes a cooling surface 41. The cooling module 4 may be, for example, a heat sink or a cooling device in which a refrigerant is circulated. A heat dissipation surface of each semiconductor module among the plurality of semiconductor modules is brought into contact with the cooling surface 41 via a bonding member 44. FIG. 2 illustrates a case in which the entireties of the semiconductor modules 2-1 and 2-5 among the plurality of semiconductor modules mounted on the mounting surface 30e of the printed circuit board 30 are covered with the bonding member 44. Four corners of the cooling module 4 are fixed to the printed circuit board 30 with screws.

The bonding member 44 may be a brazing material or thermal interface material. The brazing material contains, for example, at least one of aluminum alloy, titanium alloy, magnesium alloy, zirconium alloy, silicon alloy, or tin alloy as a main component. The thermal interface material includes various materials such as thermally conductive grease, an elastomer sheet, room temperature vulcanization (RTV) rubber, gel, and a phase change material.

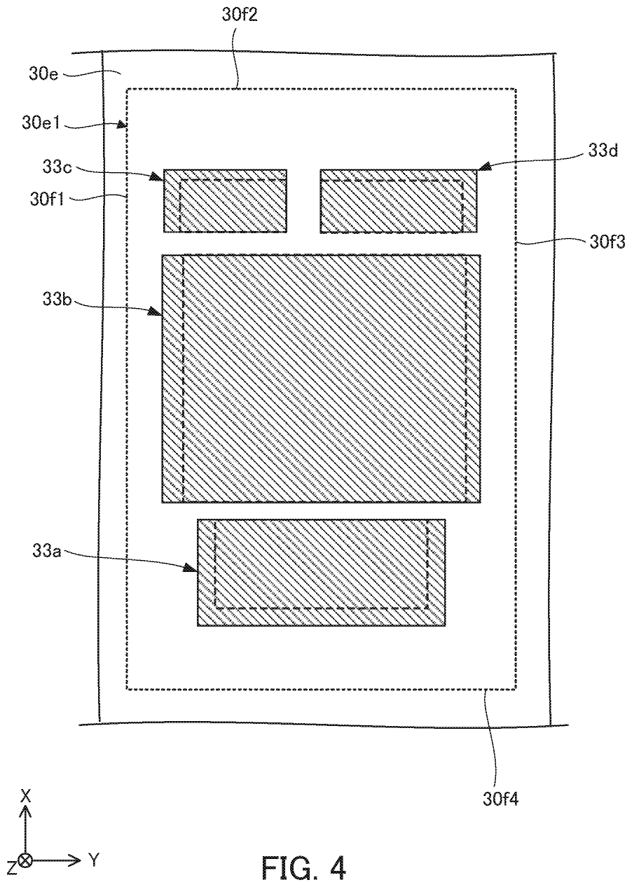

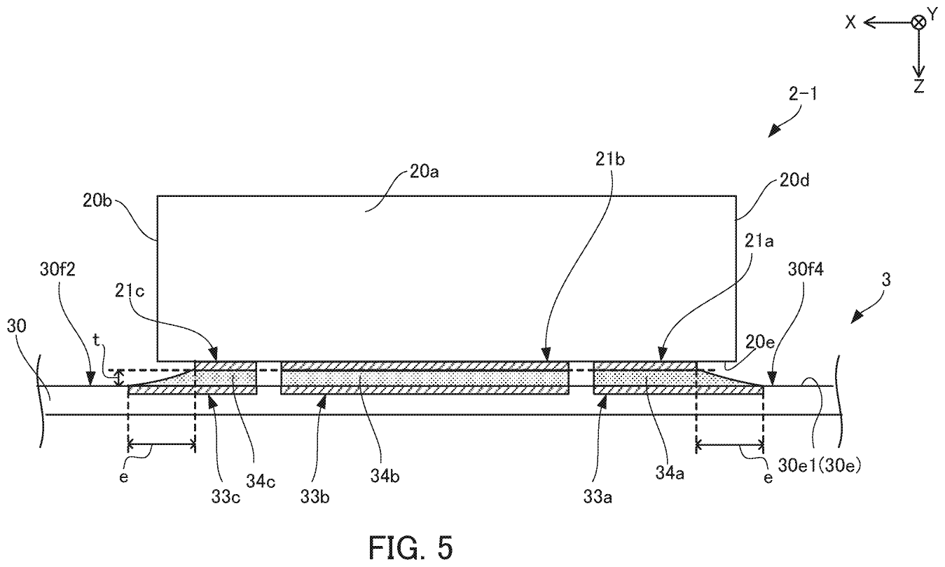

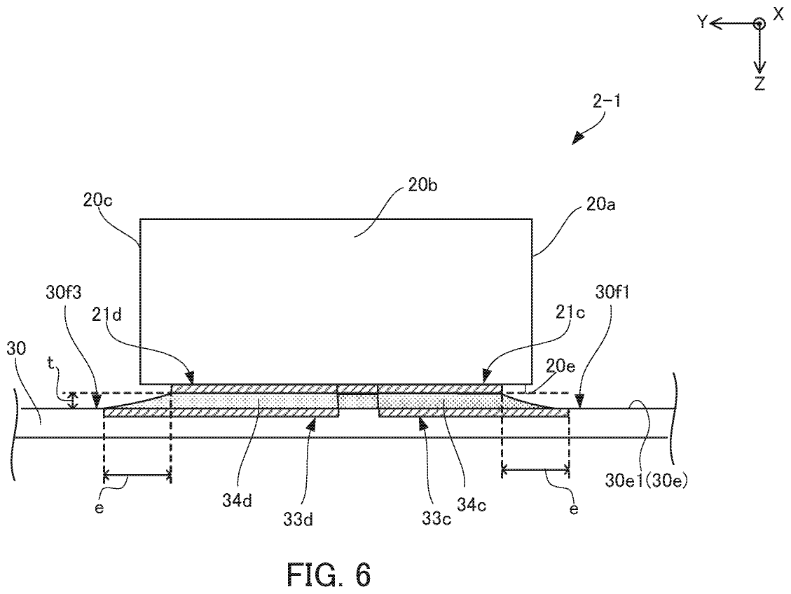

Next, details of mounting the semiconductor module to the mounting region of the printed circuit board 30 included in the wiring module 3 will be described with reference to FIGS. 4 to 6. FIG. 4 is a plan view of a mounting region of a printed circuit board included in a wiring module according to the embodiment. FIG. 5 is a first side view of the wiring module to which the semiconductor module according to the embodiment is bonded. FIG. 6 is a second side view of the wiring module to which the semiconductor module according to the embodiment is bonded.

FIG. 4 illustrates, as an example from among the plurality of mounting regions included in the mounting surface 30e of the printed circuit board 30, a mounting region 30e1 to which the semiconductor module 2-1 is mounted. A broken line in a first conductive pattern 33a in FIG. 4 indicates a position of the first electrode 21a when the semiconductor module 2-1 is mounted to the mounting region 30e1 (FIGS. 5 and 6). Broken lines depicted in a second conductive pattern 33b, a third conductive pattern 33c, and a fourth conductive pattern 33d in FIG. 4 also indicate positions of the second electrode 21b, the third electrode 21c, and the fourth electrode 21d, respectively.

The side view of FIG. 5 represents the side surface 20a of the semiconductor module 2-1 mounted on the printed circuit board 30 of FIG. 1. The side view of FIG. 6 represents the side surface 20b of the semiconductor module 2-1 mounted on the printed circuit board 30 of FIG. 1.

The mounting surface 30e of the printed circuit board 30 includes the mounting region 30e1. The mounting region 30e1 is a region where the semiconductor module 2-1 is mounted. The size of the mounting region 30e1 may be greater than the size of the electrode surface 20e of the semiconductor module 2-1. Four sides of the mounting region 30e1 are surrounded by an outer edge 30f1, an outer edge 30f2, an outer edge 30f3, and an outer edge 30f4. The outer edge 30f1 and the outer edge 30f3 extend along a longitudinal direction of the mounting region 30e1, and the outer edge 30f2 and the outer edge 30f4 extend along a short-side direction of the mounting region 30e1.

The mounting region 30e1 includes the first conductive pattern 33a, the second conductive pattern 33b, the third conductive pattern 33c, and the fourth conductive pattern 33d. As illustrated in FIGS. 5 and 6, the semiconductor module 2-1 is mounted to the mounting region 30e1 included in the mounting surface 30e of the printed circuit board 30 through solder, which is an example of a bonding member.

The first conductive pattern 33a is electrically connected to the first electrode 21a of the semiconductor module 2-1 through solder 34a. The first conductive pattern 33a is included in a predetermined conductive circuit layer of the printed circuit board 30. The first conductive pattern 33a is provided at a position corresponding to the first electrode 21a of the semiconductor module 2-1 mounted on the mounting region 30e1. The first conductive pattern 33a may have a rectangular shape in plan view, similarly to the first electrode 21a of the semiconductor module 2-1.

The first conductive pattern 33a faces the outer edge 30f1, the outer edge 30f3, and the outer edge 30f4 among the outer edges of the mounting region 30e1. Three portions of the first conductive pattern 33a that directly face the outer edge 30f1, the outer edge 30f3, and the outer edge 30f4 of the mounting region 30e1 respectively extend toward the outer edge 30f1, the outer edge 30f3, and the outer edge 30f4 beyond the first electrode 21a disposed on the first conductive pattern 33a. Each extension width e of the first conductive pattern 33a is at least twice a thickness t of the solder 34a that bonds the first conductive pattern 33a and the first electrode 21a. In FIG. 5, the extension width e of the portion of the first conductive pattern 33a facing the outer edge 30f4 is illustrated. The portions of the first conductive pattern 33a facing the outer edge 30f1 and the outer edge 30f3 also extend with the same extension width e.

The portions of the solder 34a that face the outer edge 30f1, the outer edge 30f3, and the outer edge 30f4 are formed as fillet-shaped portions. For example, as illustrated in FIG. 5, the solder 34a forms a concave curved surface connecting an end portion facing the outer edge 30f4 of the first electrode 21a and an end portion facing the outer edge 30f4 of the first conductive pattern 33a. The solder 34a also includes fillet-shaped portions (not illustrated) facing the outer edge 30f1 and the outer edge 30f3, and these portions also include concave curved surfaces.

The second conductive pattern 33b is electrically connected to the second electrode 21b of the semiconductor module 2-1 through solder 34b. The second conductive pattern 33b is included in a predetermined conductive circuit layer of the printed circuit board 30. The second conductive pattern 33b is provided at a position corresponding to the second electrode 21b of the semiconductor module 2-1 mounted on the mounting region 30e1. The second conductive pattern 33b may have a rectangular shape in plan view, similarly to the second electrode 21b of the semiconductor module 2-1.

The second conductive pattern 33b faces the outer edge 30f1 and the outer edge 30f3 among the outer edges of the mounting region 30e1. Two portions of the second conductive pattern 33b that directly face the outer edge 30f1 and the outer edge 30f3 of the mounting region 30e1 respectively extend toward the outer edge 30f1 and the outer edge 30f3 beyond the second electrode 21b disposed on the second conductive pattern 33b. Each extension width e of the second conductive pattern 33b is also at least twice a thickness t of the solder 34b that bonds the second conductive pattern 33b and the second electrode 21b. Although portions of the second conductive pattern 33b extending toward the outer edge 30f1 and the outer edge 30f3 are not illustrated, these portions extend with the extension width e similarly to other conductive patterns.

The portions of the solder 34b that face the outer edge 30f1 and the outer edge 30f3 are formed as fillet-shaped portions. The fillet-shaped portions of the solder 34b (not illustrated) also include concave curved surfaces similarly to the solder 34a.

The third conductive pattern 33c is electrically connected to the third electrode 21c of the semiconductor module 2-1 through solder 34c. The third conductive pattern 33c is included in a predetermined conductive circuit layer of the printed circuit board 30. The third conductive pattern 33c is provided at a position corresponding to the third electrode 21c of the semiconductor module 2-1 mounted on the mounting region 30e1. The third conductive pattern 33c may have a rectangular shape in plan view similarly to the third electrode 21c of the semiconductor module 2-1.

The third conductive pattern 33c faces the outer edge 30f1 and the outer edge 30f2 among the outer edges of the mounting region 30e1. Two portions of the third conductive pattern 33c that directly face the outer edge 30f1 and the outer edge 30f2 of the mounting region 30e1 respectively extend toward the outer edge 30f1 and the outer edge 30f2 beyond the third electrode 21c disposed on the third conductive pattern 33c. Each extension width e of the third conductive pattern 33c is also at least twice a thickness t of the solder 34c that bonds the third conductive pattern 33c and the third electrode 21c.

The portions of the solder 34c that face the outer edge 30f1 and the outer edge 30f2 are formed as fillet-shaped portions. As illustrated in FIG. 6, the solder 34c forms a concave curved surface connecting an end portion facing the outer edge 30f1 of the third electrode 21c and an end portion facing the outer edge 30f1 of the third conductive pattern 33c. In addition, as illustrated in FIG. 5, the solder 34c forms a concave curved surface connecting an end portion facing the outer edge 30f2 of the third electrode 21c and an end portion facing the outer edge 30f2 of the third conductive pattern 33c.

The fourth conductive pattern 33d is electrically connected to the fourth electrode 21d of the semiconductor module 2-1 through solder 34d. The fourth conductive pattern 33d is included in a predetermined conductive circuit layer of the printed circuit board 30. The fourth conductive pattern 33d is provided at a position corresponding to the fourth electrode 21d of the semiconductor module 2-1 mounted on the mounting region 30e1. The fourth conductive pattern 33d may have a rectangular shape in plan view similarly to the fourth electrode 21d of the semiconductor module 2-1.

The fourth conductive pattern 33d faces the outer edge 30f2 and the outer edge 30f3 among the outer edges of the mounting region 30e1. Two portions of the fourth conductive pattern 33d that directly face the outer edge 30f2 and the outer edge 30f3 of the mounting region 30e1 respectively extend toward the outer edge 30f2 and the outer edge 30f3 beyond the fourth electrode 21d disposed on the fourth conductive pattern 33d. Each extension width e of the fourth conductive pattern 33d is also at least twice a thickness t of the solder 34d that bonds the fourth conductive pattern 33d and the fourth electrode 21d. In FIG. 6, the extension width e of the portion of the fourth conductive pattern 33d facing the outer edge 30f3 is illustrated. The portion of the fourth conductive pattern 33d facing the outer edge 30f2 (not illustrated) also extends with the same extension width e.

The portions of the solder 34d that face the outer edge 30f2 and the outer edge 30f3 are formed as fillet-shaped portions. For example, as illustrated in FIG. 6, the solder 34d forms a concave curved surface connecting an end portion facing the outer edge 30f3 of the fourth electrode 21d and an end portion facing the outer edge 30f3 of the fourth conductive pattern 33d. The solder 34d also includes a fillet-shaped portion facing the outer edge 30f2 (not illustrated), and this portion also includes a concave curved surface.

The thicknesses t of the solder 34a, 34b, 34c, and 34d may be substantially equal to one another. Solder components constituting the solder 34a, 34b, 34c, and 34d include lead-free solder whose main component is a predetermined alloy. The predetermined alloy may include tin. Such an alloy is, for example, at least one of a tin-silver alloy, a tin-silver-copper alloy, a tin-zinc-bismuth alloy, a tin-copper alloy, a tin-silver-indium-bismuth alloy, and a tin-antimony alloy. Furthermore, the solder components may include additives. Examples of the additives include nickel, germanium, cobalt, and silicon. Therefore, examples of the solder components include at least one of silver, zinc, copper, bismuth, indium, and antimony together with tin. Furthermore, the solder components may include at least one of nickel, germanium, cobalt, and silicon.

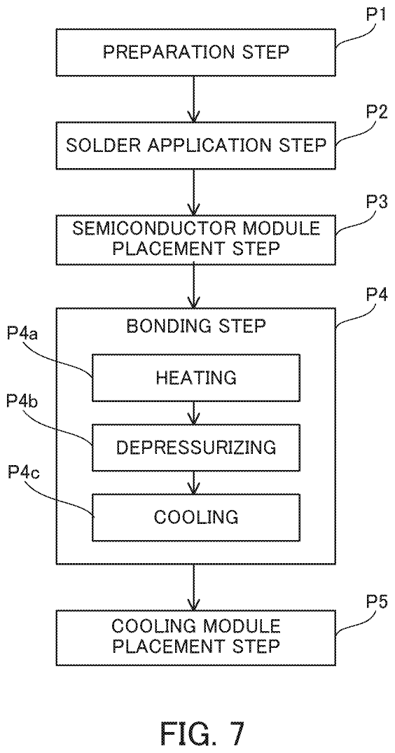

Next, a manufacturing method of the semiconductor device 1 is described using FIG. 7. FIG. 7 illustrates steps of a manufacturing method of the semiconductor device according to the embodiment. Here, mounting of the semiconductor module 2-1 to the mounting region 30e1 included in the mounting surface 30e of the wiring module 3 is described. Mounting of other semiconductor modules to other mounting regions is performed in the same manner.

A preparation step in which components of the semiconductor device 1 are prepared is performed (step P1). Examples of the components of the semiconductor device 1 include a plurality of semiconductor modules, the wiring module 3, and the cooling module 4. The semiconductor modules and the wiring module 3 may be formed in advance. Other components needed for manufacturing of the semiconductor device 1 may also be prepared. Manufacturing equipment used for manufacturing of the semiconductor device 1 may also be prepared. Examples of the manufacturing equipment include a jig used when combining the wiring module 3 and the plurality of semiconductor modules, a solder application device that applies solder, and a reflow device that heats and cools the solder.

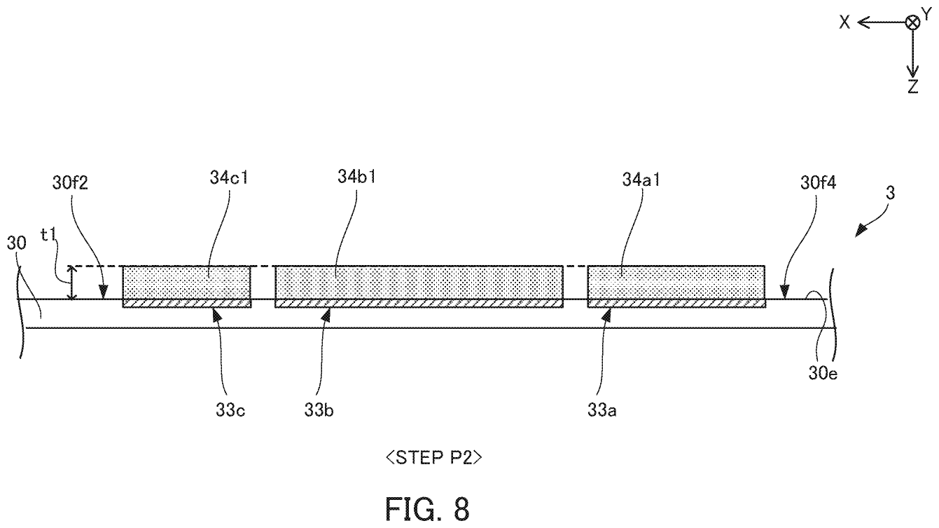

Next, a solder application step in which solder is applied to the mounting surface 30e of the wiring module 3 is performed (step P2). The solder application step is described using FIG. 8. FIG. 8 illustrates a solder application step of the manufacturing method of the semiconductor device according to the embodiment. Note that the side surfaces illustrated in FIG. 8 and FIGS. 9 to 11 correspond to the same side surface as that in FIG. 5. 74 With the mounting surface 30e of the printed circuit board 30 facing upward, the wiring module 3 is set in a predetermined region of an assembly jig. Cream solder is applied respectively to the first conductive pattern 33a, the second conductive pattern 33b, the third conductive pattern 33c, and the fourth conductive pattern 33d included in the mounting region 30e1 on the mounting surface 30e. For example, in the solder application, a metal mask having openings formed at positions corresponding to solder application regions is set on the mounting surface 30e of the printed circuit board 30. Solder is placed on the metal mask, and a squeegee is used to transfer the solder to the solder application regions. FIG. 8 illustrates a case in which solder 34a1, solder 34b1, and solder 34c1 are applied respectively to the first conductive pattern 33a, the second conductive pattern 33b, and the third conductive pattern 33c in the mounting region 30e1. The solder 34a1 is applied over an entire surface of the first conductive pattern 33a. The same applies to the second conductive pattern 33b, the third conductive pattern 33c, and the fourth conductive pattern 33d. The applied solder has a thickness t1. The thickness t1 is greater than the thickness t illustrated in FIG. 5. The thickness t1 is approximately twice the thickness t.

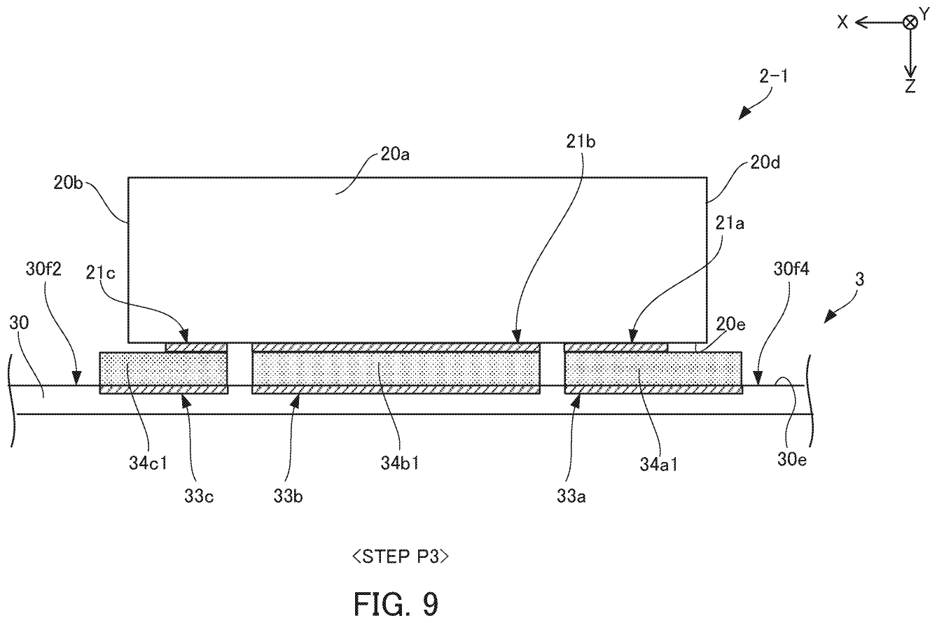

Next, a semiconductor module placement step in which the semiconductor modules 2 are placed on the wiring module 3 is performed (step P3). The semiconductor module placement step is described using FIG. 9. FIG. 9 illustrates a semiconductor module placement step of the manufacturing method of the semiconductor device according to the embodiment. A plurality of semiconductor modules is placed respectively on the mounting surface 30e of the printed circuit board 30 of the wiring module 3 through the solder. As illustrated in FIG. 9, the first electrode 21a of the semiconductor module 2-1 is placed, through the solder 34a1, on the first conductive pattern 33a in the mounting region 30e1 on the mounting surface 30e. Likewise, the second electrode 21b is placed, through the solder 34b1, on the second conductive pattern 33b. The third electrode 21c is placed, through the solder 34c1, on the third conductive pattern 33c. The fourth electrode 21d is placed, through the solder, on the fourth conductive pattern 33d (not illustrated). At this time, the solder 34a1 extends from the first electrode 21a toward the outer edge 30f1, the outer edge 30f3, and the outer edge 30f4. The solder 34b1 extends from the second electrode 21b toward the outer edge 30f1 and the outer edge 30f3. The solder 34c1 extends from the third electrode 21c toward the outer edge 30f1 and the outer edge 30f2. The solder applied to the fourth conductive pattern 33d extends from the fourth electrode 21d toward the outer edge 30f2 and the outer edge 30f3 (not illustrated).

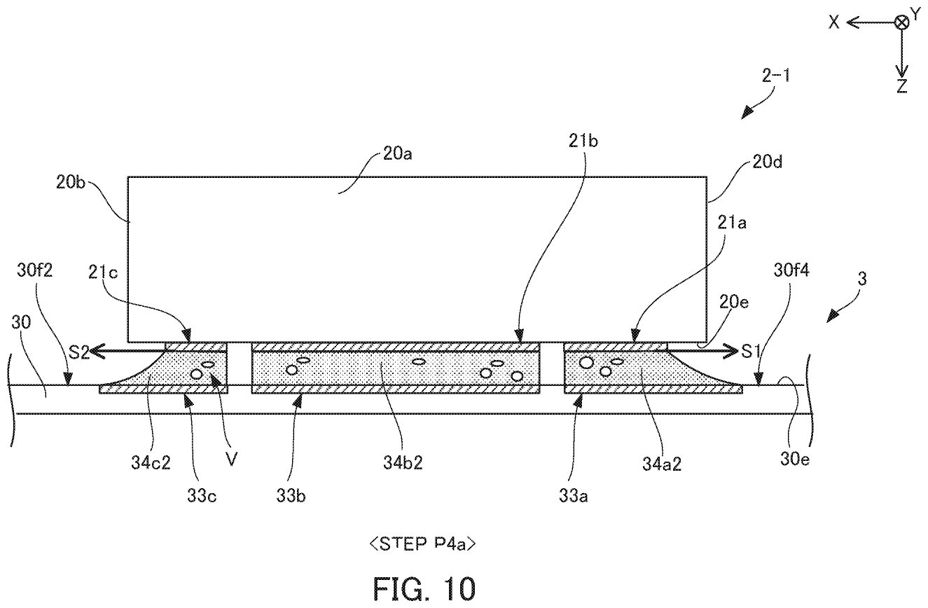

Next, a bonding step in which the plurality of semiconductor modules is bonded to the wiring module 3 with solder is performed (step P4). The bonding step includes a heating step (step P4a), a depressurizing step (step P4b), and a cooling step (step P4c). First, the step P4a is described using FIG. 10. FIG. 10 illustrates the bonding step (heating) of the manufacturing method of the semiconductor device according to the embodiment. The wiring module 3 on which the plurality of semiconductor modules has been placed respectively through the solder in step P3 is transferred, for example, into a reflow device. When the wiring module 3 on which the plurality of semiconductor modules has been placed respectively through the solder is transported to a predetermined position inside the reflow device, the wiring module 3 is heated.

For example, as illustrated in FIG. 10, molten solder 34a2 obtained by melting the solder 34a1 forms a fillet shape including a concave curved surface between the first conductive pattern 33a and the first electrode 21a, the concave curved surface connecting an end portion on a side of the outer edge 30f4 of the first conductive pattern 33a and an end portion on a side of the outer edge 30f4 of the first electrode 21a. The solder 34a2 also forms fillet shapes including concave curved surfaces on sides of the outer edge 30f1 and the outer edge 30f3 of the first conductive pattern 33a.

Solder 34b2 also forms fillet shapes including concave curved surfaces, the concave curved surfaces connecting end portions on sides of the outer edge 30f1 and the outer edge 30f3 of the second conductive pattern 33b and end portions on sides of the outer edge 30f1 and the outer edge 30f3 of the second electrode 21b (not illustrated).

Solder 34c2 forms a fillet shape including a concave curved surface connecting an end portion on a side of the outer edge 30f2 of the third conductive pattern 33c and an end portion on a side of the outer edge 30f2 of the third electrode 21c. The solder 34c2 also forms a fillet shape including a concave curved surface on a side of the outer edge 30f1 of the third conductive pattern 33c.

The solder between the fourth conductive pattern 33d and the fourth electrode 21d (not illustrated) also forms fillet shapes including concave curved surfaces on respective sides of the outer edge 30f2 and the outer edge 30f3 of the fourth conductive pattern 33d.

That is, portions of the solder that face the outer edge 30f1, the outer edge 30f2, the outer edge 30f3, and the outer edge 30f4 each form a fillet shape including a concave curved surface. For example, in FIG. 10, a portion of the solder 34a2 facing the outer edge 30f4 forms a fillet shape. Thus, a surface tension S1 directed toward the outer edge 30f4 is generated on an outer surface of the solder 34a2 in contact with the first electrode 21a. On the other hand, a surface tension S2 directed toward the outer edge 30f2 is generated on an outer surface of the solder 34c2 in contact with the third electrode 21c. In this manner, the semiconductor module 2-1 is pulled outward by the surface tension S1 parallel to a longitudinal direction and the surface tension S2 in an opposite direction. The semiconductor module 2-1 has solder facing the outer edge 30f1 and the outer edge 30f3 that also form respective fillet shapes, and outward surface tension is generated in each of these portions. In this manner, the semiconductor module 2-1 is pulled outward by the surface tension parallel to a short-side direction and the surface tension in an opposite direction. Accordingly, the semiconductor module 2-1 becomes substantially parallel to the mounting surface 30e (the mounting region 30e1) of the printed circuit board 30 with no inclination.

When the solder 34a1 is heated and melts into the solder 34a2, voids V are generated in the solder 34a2. The voids V are also generated in other solder. When the solder 34a1 is heated, flux components contained in the solder 34a1 vaporize, and portions where the flux components had existed become the voids V. Moisture adhering to at least one of the first electrode 21a and the first conductive pattern 33a, as well as bubbles entrapped during application of the solder 34a1, also become causes of generating the voids V.

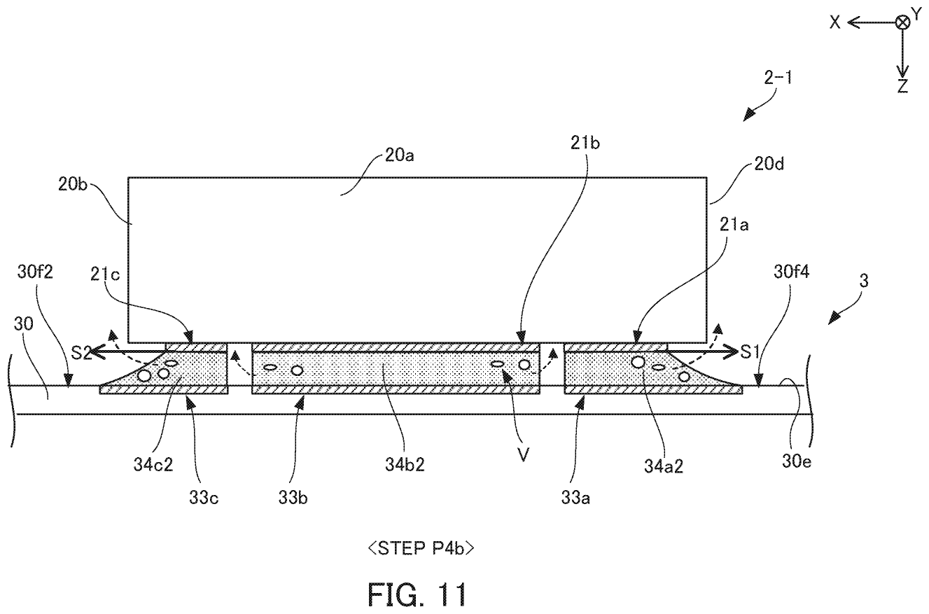

Next, the depressurizing step (step P4b) will be described with reference to FIG. 11. FIG. 11 illustrates the bonding step (heating and depressurizing) of the manufacturing method of the semiconductor device according to the embodiment. While heating started in step P4a is continued, the inside of the reflow apparatus is depressurized. As a result, the voids V in the solder are released, and the voids V in the solder are reduced.

Portions of the solder that respectively face the outer edge 30f1, the outer edge 30f2, the outer edge 30f3, and the outer edge 30f4 are formed as fillet-shaped portions. The voids V readily escape from concave curved surfaces of the fillet-shaped solder. For example, as indicated in FIG. 11, the voids V readily escape from a curved surface of the solder 34a2 on a side of the outer edge 30f4. Similarly, the voids V readily escape from a curved surface of the solder 34c2 on a side of the outer edge 30f2. Accordingly, since the portions of the solder facing the outer edge 30f1, the outer edge 30f2, the outer edge 30f3, and the outer edge 30f4 are formed as fillet-shaped portions, the voids V contained in the solder are further reduced.

Next, cooling (step P4c) is performed. Heating and depressurizing in the reflow apparatus are gradually decreased and finally stopped. Along with this, the temperature inside the reflow apparatus decreases, and the pressure becomes atmospheric pressure. For example, the solder 34a2, the solder 34b2, and the solder 34c2 indicated in FIG. 11 harden. At this time, the semiconductor module 2-1 is bonded to the mounting region 30e1 included in the mounting surface 30e of the printed circuit board 30 by the hardened solder 34a, solder 34b, and solder 34c obtained from the solder 34a2, solder 34b2, and solder 34c2. In this step, thicknesses of the solder 34a, solder 34b, and solder 34c become the thickness t. The thickness t is half of the thickness t1. The semiconductor module 2-1 is maintained substantially parallel to the mounting surface 30e of the printed circuit board 30. Therefore, the semiconductor module 2-1 is bonded to the mounting region 30e1 on the mounting surface 30e of the printed circuit board 30 while the semiconductor module 2-1 is maintained parallel to the mounting surface 30e without pressing the semiconductor module 2-1 against the mounting surface 30e. In this case, the semiconductor module 2-1 may also be pressed against the mounting surface 30e of the printed circuit board 30. In this case, the semiconductor module 2-1 is more reliably bonded to the mounting region 30e1 of the mounting surface 30e of the printed circuit board 30 while the semiconductor module 2-1 is maintained substantially horizontal. Accordingly, as indicated in FIGS. 5 and 6, the semiconductor module 2-1 is bonded to the mounting region 30e1 of the printed circuit board 30.

Next, a cooling module placement step (step P5) is performed in which the cooling module is arranged with respect to the plurality of semiconductor modules. For example, the bonding member 44 is previously applied to the cooling surface 41 of the cooling module 4. The wiring module 3 on which the plurality of semiconductor modules is mounted is arranged with respect to the cooling surface 41. In this step, the plurality of semiconductor modules is sandwiched between the cooling module 4 and the wiring module 3. As a result, the bonding member 44 spreads between the cooling surface 41 of the cooling module 4 and the mounting surface 30e of the wiring module 3, and the plurality of semiconductor modules is covered. Furthermore, four corners of the printed circuit board 30 of the wiring module 3 are fastened to the cooling module 4 using screws. Thus, for example, a thickness of the bonding member 44 between the heat dissipation surface 20f of the semiconductor module 2-1 and the cooling surface 41 of the cooling module 4 is made thin and substantially uniform. The same applies to other semiconductor modules. As indicated in FIG. 2, the semiconductor device 1 is obtained.

Here, another semiconductor device will be described. The other semiconductor device is also manufactured along the process illustrated in FIG. 7, similarly to the semiconductor device 1. In the other semiconductor device, shapes and sizes of the first conductive pattern and the first electrode are the same as each other. Shapes and sizes of the second conductive pattern and the second electrode, the third conductive pattern and the third electrode, and the fourth conductive pattern and the fourth electrode are also the same, respectively. Other configurations of the other semiconductor device may be the same as configurations of the semiconductor device 1. In the other semiconductor device, step P4b (depressurizing) in FIG. 7 is not performed.

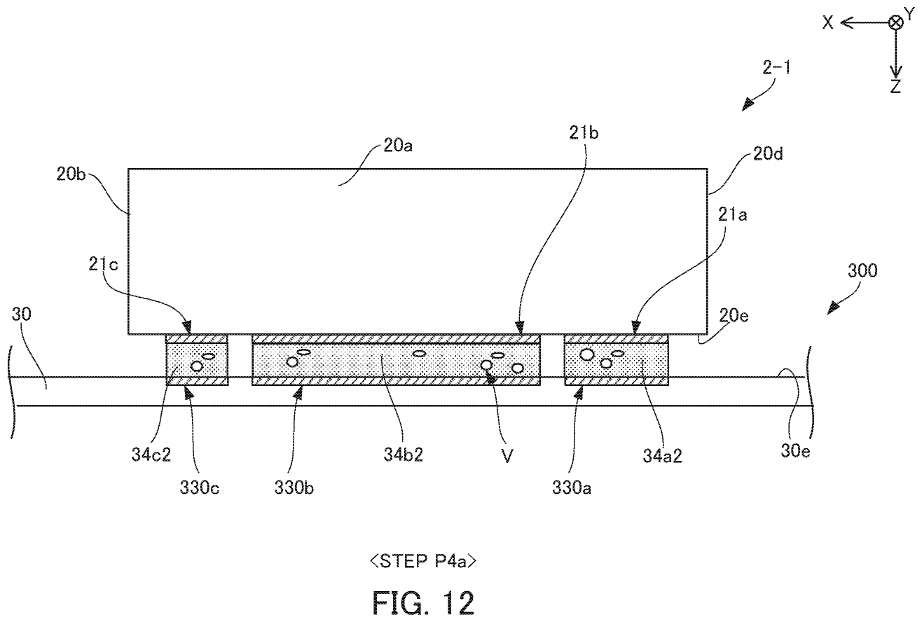

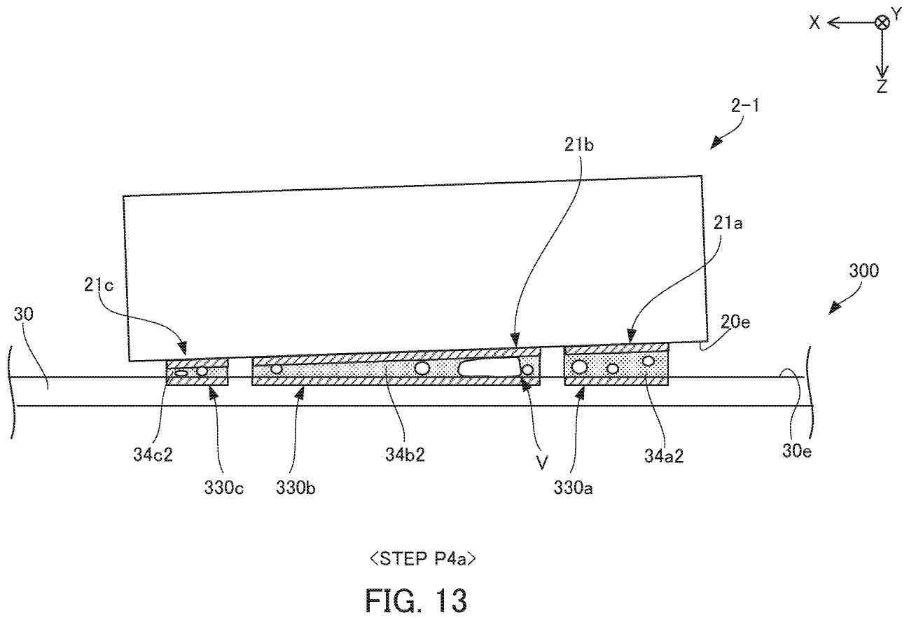

A different semiconductor device is described below with reference to FIG. 7 and FIGS. 12 and 13. FIG. 12 and FIG. 13 respectively illustrate a bonding step (heating) of a manufacturing method of the different semiconductor device. FIG. 12 and FIG. 13 correspond to FIG. 10, which represents the semiconductor device 1.

In manufacturing the different semiconductor device, steps P1 to P3 of FIG. 7 are sequentially performed, and the heating step (step P4a) for heating a plurality of semiconductor modules placed on a wiring module 300 via solder is performed. For example, as illustrated in FIG. 12, a first conductive pattern 330a of the printed circuit board 30 and the first electrode 21a have the same size. The solder 34a2 located between the first conductive pattern 330a and the first electrode 21a is heated and melted, and the voids V occur therein. The same applies to a second conductive pattern 330b and the second electrode 21b, and to a third conductive pattern 330c and the third electrode 21c. Similarly, the solder 34b2 and the solder 34c2 are melted, and the voids V occur therein.

When the heating is further continued, additional voids V occur in the solder 34a2, the solder 34b2 and the solder 34c2. For example, as represented in FIG. 13, the multiple voids V occurring in the solder 34b2 aggregate into one large void V.

Furthermore, when the solder 34a2, the solder 34b2, and the solder 34c2 on the printed circuit board 30 are heated, flux components are released, and the solder 34a2, the solder 34b2, and the solder 34c2 are pressed by the semiconductor module 2-1. Thus, the thicknesses of the solder 34a2, the solder 34b2, and the solder 34c2 become thinner. In this case, as indicated in FIG. 13, when a large void V is included in the solder 34b2, the semiconductor module 2-1 fails to compress the void V, and the semiconductor module 2-1 becomes inclined with respect to the printed circuit board 30. When cooling (step P4c) is performed in this inclined state, the semiconductor module 2-1 is bonded to the printed circuit board 30 while remaining inclined.

Next, the cooling module placement step is performed (step P5). The cooling module 4 is attached to the semiconductor module 2-1 that is bonded to the printed circuit board 30 in an inclined state, via the bonding member 44. Thus, the different semiconductor device is obtained.

As described above, the semiconductor module 2-1 is inclined. Therefore, the thickness of the bonding member 44 between the heat dissipation surface 20f of the semiconductor module 2-1 and the cooling surface 41 of the cooling module 4 becomes non-uniform, leading to a reduction in heat dissipation performance of the semiconductor module 2-1. The same applies to other semiconductor modules that are also inclined.

A case where depressurizing (step P4b) is performed after heating (step P4a) in order to remove the voids V causing inclination during manufacturing of the different semiconductor device is now described. In the manufacturing of the different semiconductor device, the heating step (step P4a) for heating a plurality of semiconductor modules placed on the wiring module 300 via solder is performed. As described above, the voids V occur in the solder 34a2, the solder 34b2 and the solder 34c2, as illustrated in FIG. 12.

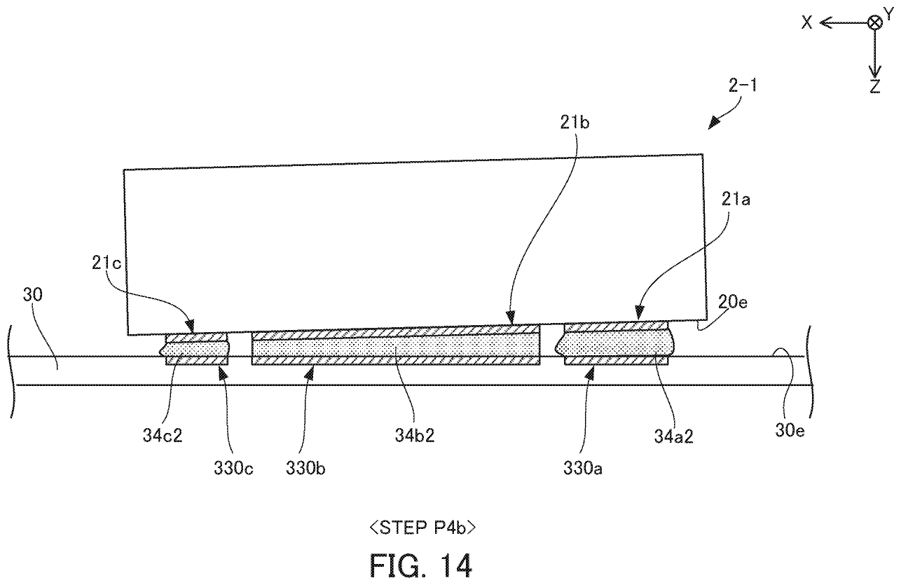

Next, the depressurizing step (step P4b) is described with reference to FIG. 14. FIG. 14 illustrates the bonding step (heating and depressurizing) of the manufacturing method of the different semiconductor device. While heating is performed, the interior of the reflow apparatus is depressurized. Thus, as represented in FIG. 14, the voids V are removed from the solder 34a2, the solder 34b2 and the solder 34c2.

Then, the semiconductor module 2-1 is naturally positioned by self-alignment caused by cohesive forces of the melted solder 34a2, 34b2 and 34c2. The first electrode 21a of the semiconductor module 2-1 and the first conductive pattern 330a of the printed circuit board 30 have the same shape and size. The same applies to the second electrode 21b and the second conductive pattern 330b, the third electrode 21c and the third conductive pattern 330c, and the fourth electrode 21d and a fourth conductive pattern (not illustrated). On the other hand, the first electrode 21a, the second electrode 21b, the third electrode 21c, and the fourth electrode 21d on the electrode surface 20e of the semiconductor module 2-1 have different respective sizes. Furthermore, their placement positions on the electrode surface 20e are neither line-symmetric nor point-symmetric and are irregular. Therefore, magnitudes of surface tensions generated in the solder 34a2, the solder 34b2 and the solder 34c2 are not uniform. Consequently, the semiconductor module 2-1 aligned by self-alignment becomes inclined with respect to the mounting surface 30e of the printed circuit board 30. In addition, the semiconductor module 2-1 may be displaced toward one of the outer edges 30f1, 30f2, 30f3 and 30f4 in plan view. Particularly, when the semiconductor module 2-1 has a rectangular shape in plan view, the semiconductor module 2-1 tends to be displaced toward one side in the longitudinal direction. When cooling (step P4c) is performed in this state, the semiconductor module 2-1 is bonded to the printed circuit board 30 in an inclined state. Consequently, as in the case of the above-described different semiconductor device, the thickness of the bonding member 44 between the heat dissipation surface 20f of the semiconductor module 2-1 and the cooling surface 41 of the cooling module 4 becomes non-uniform, leading to a reduction in heat dissipation performance of the semiconductor module 2-1. The same applies to other semiconductor modules that are also inclined.

Accordingly, the semiconductor device 1 includes the semiconductor module 2-1 and the printed circuit board 30 on which the semiconductor module 2-1 is mounted. In the semiconductor module 2-1, the first electrode 21a, the second electrode 21b, the third electrode 21c, and the fourth electrode 21d are provided on the electrode surface 20e. The printed circuit board 30 includes the mounting surface 30e on which the semiconductor module 2-1 is mounted, and the mounting region 30e1 corresponding to a shape of the semiconductor module 2-1 is defined on the mounting surface 30e. The mounting surface 30e has the first conductive pattern 33a, the second conductive pattern 33b, the third conductive pattern 33c, and the fourth conductive pattern 33d in the mounting region 30e1, corresponding respectively to the first electrode 21a, the second electrode 21b, the third electrode 21c, and the fourth electrode 21d. The first electrode 21a, the second electrode 21b, the third electrode 21c, and the fourth electrode 21d are bonded to the first conductive pattern 33a, the second conductive pattern 33b, the third conductive pattern 33c, and the fourth conductive pattern 33d, respectively, via the solder 34a, the solder 34b, the solder 34c, and the solder 34d. In this case, portions of the first conductive pattern 33a, the second conductive pattern 33b, the third conductive pattern 33c, and the fourth conductive pattern 33d that face the outer edges 30f1, 30f2, 30f3, and 30f4 of the mounting region 30e1 extend, respectively, toward the corresponding outer edges 30f1, 30f2, 30f3, and 30f4 beyond the first electrode 21a, the second electrode 21b, the third electrode 21c, and the fourth electrode 21d.

In the semiconductor device 1 described above, the semiconductor module 2-1 becomes substantially parallel to the mounting surface 30e of the printed circuit board 30. The cooling module 4 is placed, via the bonding member 44, on the heat dissipation surface 20f located on the opposite side of the electrode surface 20e of the semiconductor module 2-1. Because the semiconductor module 2-1 is substantially parallel to the printed circuit board 30, the thickness of the bonding member 44 between the heat dissipation surface 20f and the cooling module 4 becomes uniform. As a result, degradation of heat dissipation performance of the semiconductor device 1 is prevented.

When the first conductive pattern 33a and the first electrode 21a, the second conductive pattern 33b and the second electrode 21b, the third conductive pattern 33c and the third electrode 21c, and the fourth conductive pattern 33d and the fourth electrode 21d have the same shape and size, and when the semiconductor module 2-1 has a rectangular shape in plan view (the side surfaces 20a and 20c define a longitudinal direction), the semiconductor module 2-1 tends to be displaced toward one side in the longitudinal direction, as described above. In such a case, portions of the first conductive pattern 33a, the third conductive pattern 33c, and the fourth conductive pattern 33d that face the short-side direction (the side surfaces 20b and 20d) in plan view may extend in the longitudinal direction.

Inclination of the semiconductor module 2-1 was measured in accordance with the solder thickness t and the extension width e (FIGS. 5 and 6) of the conductive pattern relative to the electrode. Specifically, inclination of the semiconductor module 2-1 was measured in cases where the solder thickness t was 100 μm (the solder thickness t1 was 200 μm) and 50 μm (the solder thickness t1 was 100 μm), for extension widths e of 0 mm, 0.1 mm, and 0.3 mm. Inclination was defined as a difference between maximum and minimum heights of four corners of the semiconductor module 2-1.

According to the results, when the solder thickness t was 100 μm (the solder thickness t1 was 200 μm), inclination of the semiconductor module 2-1 was suppressed with an extension width e of 0.3 mm or greater. The extension width e in this case corresponds to three times or more the solder thickness t.

Furthermore, when the solder thickness t was 50 μm (the solder thickness t1 was 100 μm), inclination of the semiconductor module 2-1 was suppressed with an extension width e of 0.1 mm or greater. The extension width e in this case corresponds to two times or more the solder thickness t.

From these results, it is preferable that the extension width e of the conductive pattern be two times or more the solder thickness t in order to reliably reduce inclination of the semiconductor module 2-1 with respect to the mounting surface 30e of the printed circuit board 30.

According to the disclosed technique, it is possible to reduce inclination of an electronic module relative to a printed circuit board.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic device, comprising:
an electronic module including a plurality of electrodes provided on a principal surface thereof; and
a printed circuit board, including:
a mounting surface on which the electronic module is mounted, a mounting region being defined on the mounting surface, and
a plurality of conductive patterns provided in the mounting region, the plurality of conductive patterns respectively corresponding to the plurality of electrodes and being respectively bonded to the plurality of electrodes via a bonding member, wherein
each of the plurality of conductive patterns has at least one portion that faces an outer edge of the mounting region and extends toward the outer edge beyond one of the plurality of electrodes corresponding to said each conductive pattern.

2. The electronic device according to claim 1, wherein:
a center of gravity of the plurality of electrodes does not coincide with a center of gravity of the principal surface of the electronic module.

3. The electronic device according to claim 1, wherein:
the plurality of electrodes, in a plan view of the electronic device, is not uniform in shape, size or both.

4. The electronic device according to claim 1, wherein:
the plurality of electrodes is provided asymmetrically with respect to a center of the principal surface of the electronic module.

5. The electronic device according to claim 1, wherein:
the principal surface of the electronic module is of a rectangular shape, including a long side and a short side, in a plan view of the electronic device,
the outer edge of the mounting region has a pair of first sides extending along the short side of the rectangular shape, and
the plurality of conductive patterns includes a plurality of portions that face the pair of first sides, and that extend toward the pair of first sides.

6. The electronic device according to claim 1, wherein:
a length of said at least one portion, in a direction of said at least one portion extending toward the outer edge, is two times or more a thickness of the bonding member.

7. A method of manufacturing an electronic device, the method comprising:
preparing
an electronic module including a plurality of electrodes provided on a principal surface thereof, and
a printed circuit board including:
a mounting surface on which a mounting region corresponding to a shape of the electronic module is defined, and
a plurality of conductive patterns provided in the mounting region and respectively corresponding to the plurality of electrodes; and
bonding the plurality of electrodes of the electronic module respectively to the plurality of conductive patterns of the printed circuit board via a bonding member,
wherein each of the plurality of conductive patterns has at least one portion that faces an outer edge of the mounting region and extends toward the outer edge beyond one of the plurality of electrodes corresponding to said each conductive pattern.

8. The method according to claim 7, wherein:
the bonding of the plurality of electrodes includes placing the plurality of electrodes of the electronic module on the plurality of conductive patterns of the printed circuit board via the bonding member, heating, and depressurizing.

9. The method according to claim 7, wherein:
the preparing includes
preparing the electronic module in plurality and defining the mounting region in plurality, the plurality of mounting regions corresponding to the plurality of electronic modules, on the mounting surface of the printed circuit board, the plurality of conductive patterns being provided in each of the plurality of mounting regions, and
the bonding of the plurality of electrodes includes bonding, via the bonding member, the plurality of electrodes of each of the plurality of electronic modules respectively to the plurality of conductive patterns provided in one of the plurality of mounting regions corresponding to said each electronic module.

10. The method according to claim 9, wherein:
the bonding of the plurality of electrodes is performed while pressing said each of the plurality of electronic modules against the plurality of conductive patterns.
